(19) United States
(12) Patent Application Publication
(10) Pub. No.: US 2013/0180448 A1
(43) Pub. Date: Jul. 18, 2013

(54) SUBSTRATE TRANSFER DEVICE AND SUBSTRATE PROCESSING SYSTEM

(71) Applicants: Hiromitsu Sakaue, Nirasaki City (JP); Masahito Ozawa, Nirasaki City (JP); Yuichi Furuya, Nirasaki City (JP); Nanako Shinoda, Nirasaki City (JP); Katsuhito Hirose, Nirasaki City (JP); Morihito Inagaki, Kurokawa-gun (JP)

(72) Inventors: Hiromitsu Sakaue, Nirasaki City (JP); Masahito Ozawa, Nirasaki City (JP); Yuichi Furuya, Nirasaki City (JP); Nanako Shinoda, Nirasaki City (JP); Katsuhito Hirose, Nirasaki City (JP); Morihito Inagaki, Kurokawa-gun (JP)

(73) Assignee: Tokyo Electron Limited, Tokyo (JP)

(21) Appl. No.: 13/549,046

(22) Filed: Jul. 13, 2012

(30) Foreign Application Priority Data
Jul. 15, 2011 (JP) 2011-157162
Mar. 29, 2012 (JP) 2012-077694

(51) Int. Cl. H01L 21/677

(52) U.S. Cl. CPC H01L 21/67739
USPC 118/696

(57) ABSTRACT

A substrate transfer device includes a pick which has positioning pins to position a substrate and holds a positioned substrate; a drive unit which drives the pick such that the substrate is loaded/unloaded to/from a vacuum processing unit by using a pick; and a transfer control unit which controls a transfer operation of the substrate using the pick. The transfer control unit obtains in advance information on a reference position of the substrate at room temperature when the substrate is loaded into the vacuum processing unit, calculates a positional deviation from the reference position of the substrate when the substrate is loaded into the vacuum processing unit in actual processing, and controls a drive unit such that the substrate is loaded into the vacuum processing unit by correcting the positional deviation.

### CROSS-REFERENCE TO RELATED APPLICATIONS

This application claims priority to Japanese Patent Application No. 2011-157162 filed on Jul. 15, 2011 and Japanese Patent Application No. 2012-077694 filed on Mar. 29, 2012, the entire contents of which are incorporated herein by reference.

### FIELD OF THE INVENTION

The present invention relates to, e.g., a substrate transfer device being used in a substrate processing apparatus performing a vacuum process accompanied by heat on a substrate such as a semiconductor wafer, and a substrate processing system.

### BACKGROUND OF THE INVENTION

In a process of manufacturing a semiconductor device, a vacuum process such as a film formation process is frequently used on a substrate to be processed, i.e., a semiconductor wafer (hereinafter simply referred to as a wafer). In recent years, in terms of improving the efficiency of vacuum processing and suppressing contamination such as oxidation or dust, there has been used a multi-chamber type (cluster tool type) vacuum processing system in which a plurality of vacuum processing units are connected to a transfer chamber maintained in vacuum and the wafer is transferred to each of the vacuum processing units by a substrate transfer device provided in the transfer chamber (see, e.g., Japanese Patent Application Publication No. 2000-208589).

In this multi-chamber type processing system, in addition to the above-described vacuum processing units, load-lock chambers are connected to the transfer chamber maintained in vacuum such that the wafer can be transferred to the transfer chamber maintained in vacuum from wafer cassettes placed in the atmosphere. The transfer of the wafer is performed between the vacuum processing units or between the vacuum processing unit and the load-lock chamber by the substrate transfer device provided in the transfer chamber.

In the substrate transfer device being used in this case, a pick for holding the wafer, which is configured to hold only a bottom bevel or backside of the wafer, is employed.

Recently, it is required to perform the transfer of the wafer at a high speed for high-throughput processing. However, in case of using the pick holding only a bottom bevel or backside of the wafer as described above, when the wafer is transferred at a high speed, the wafer slips and positional accuracy of the wafer is lowered. In addition, if a process accompanied by heat such as a film formation process is performed, the positional accuracy may be further degraded by errors due to thermal expansion.

### SUMMARY OF THE INVENTION

In view of the above, the present invention provides a substrate transfer device capable of increasing positional accuracy of a substrate even if the substrate is transferred at a high speed in a substrate processing apparatus performing a process accompanied by heat in vacuum, and a substrate processing system.

In accordance with a first aspect of the present invention, there is provided a substrate transfer device, which is provided in a transfer chamber to perform loading/unloading of a substrate to/from a vacuum processing unit in a substrate processing system including the vacuum processing unit in which a vacuum process accompanied by heat is performed and the transfer chamber connected to the vacuum processing unit and maintained in vacuum, the substrate transfer device including: a pick which has one or more positioning pins to position the substrate and holds the positioned substrate; a drive unit which drives the pick such that the substrate is loaded/unloaded to/from the vacuum processing unit by using the pick; and a transfer control unit which controls a transfer operation of the substrate using the pick, wherein the transfer control unit obtains in advance information on a reference position of the substrate at room temperature when the substrate is loaded into the vacuum processing unit, calculates a positional deviation from the reference position of the substrate when the substrate is loaded into the vacuum processing unit in actual processing, and controls the drive unit such that the substrate is loaded into the vacuum processing unit by correcting the positional deviation.

In accordance with a second aspect of the present invention, there is provided a substrate processing system including: a vacuum processing unit in which a vacuum process accompanied by heat is performed; a transfer chamber connected to the vacuum processing unit and maintained in vacuum; and a substrate transfer device provided in the transfer chamber to perform loading/unloading of a substrate to/from the vacuum processing unit, wherein the substrate transfer device includes: a pick which has one or more positioning pins to position the substrate and holds the positioned substrate; a drive unit which drives the pick such that the substrate is loaded/unloaded to/from the vacuum processing unit by using the pick; and a transfer control unit which controls a transfer operation of the substrate using the pick, wherein the transfer control unit obtains in advance information on a reference position of the substrate at room temperature when the substrate is loaded into the vacuum processing unit, calculates a positional deviation from the reference position of the substrate when the substrate is loaded into the vacuum processing unit in actual processing, and controls the drive unit such that the substrate is loaded into the vacuum processing unit by correcting the positional deviation.

The positioning pins may be arranged on the pick such that the substrate is interposed between the positioning pins, and the substrate may be positioned by pressing the substrate against the positioning pins by inertia when the pick is moved.

Further, the pick may have a plurality of the positioning pins and the substrate transfer device may further include a clamping mechanism to clamp the substrate on the pick by moving any one of the plurality of positioning pins.

The substrate transfer device may further include a multi-joint arm mechanism including the pick and arms, wherein the pick is rotatably provided with respect to an adjacent one of the arms, wherein the clamping mechanism includes a cam which is displaced according to rotation of the pick, a moving member which moves the positioning pins back and forth by displacement of the cam to clamp or release the substrate, and an intermediate mechanism which transmits the displacement of the cam to the moving member, and wherein a position of the cam is adjusted such that a back and forth movement of the positioning pins is determined in synchronization with a rotational position of the pick.

The positioning pins may include leading end side positioning pins provided on a leading end side of the pick and base end side positioning pins provided a base end side of the pick, and the clamping mechanism is configured to clamp or release the substrate by moving the base end side positioning pins back and forth, and wherein the substrate is released in a range in which the pick has a negative acceleration when releasing the substrate on the pick to deliver the substrate by extending the multi-joint arm mechanism, and the substrate is clamped in a range in which the pick has a positive acceleration when clamping the substrate after receiving the substrate on the pick by retracting the multi-joint arm mechanism.

The reference position information may be obtained based on detection information obtained by detecting the substrate at room temperature by a position detection sensor unit provided at a position where the substrate to be loaded/unloaded to/from the vacuum processing unit passes by. Position information of the substrate when loading the substrate into the vacuum processing unit may be obtained based on detection information obtained by detecting the substrate by the position detection sensor unit and a positional deviation may be calculated from the position information of the substrate and the reference position information. Detection of the positional deviation may be performed when unloading the substrate from the vacuum processing unit or when loading the substrate into the vacuum processing unit, and correction of the positional deviation may be performed when loading the substrate into the vacuum processing unit.

Further, the substrate processing system may further include a load-lock chamber which is connected to the transfer chamber and has a variable pressure between atmospheric ambience and vacuum to transfer the substrate in the air atmosphere to the transfer chamber in the vacuum state, wherein the transfer control unit obtains in advance information on a reference position of the substrate at room temperature when the substrate is loaded into the load-lock chamber, calculates a positional deviation from the reference position of the substrate when the substrate is loaded into the load-lock chamber in actual processing, and controls the drive unit such that the substrate is loaded into the load-lock chamber by correcting the positional deviation.

Each of the positioning pins of the pick may have a ring member rotatable about a vertical axis. The pick may include backside supporting pads swing to support a backside of the substrate and having rollers rotatable in a movement direction when positioning the substrate.

According to the present invention, since the drive unit is controlled to obtain in advance information on a reference position of the substrate at room temperature when the substrate is loaded into the vacuum processing unit, calculate a positional deviation from the reference position of the substrate when the substrate is loaded into the vacuum processing unit in actual processing, and control the drive unit such that the substrate is loaded into the vacuum processing unit by correcting the positional deviation, in the substrate processing apparatus performing a process accompanied by heat in vacuum, it is possible to suppress the positional deviation of the substrate even if the substrate is transferred at a high speed, correct thermal expansion or the like and increase the positional accuracy of the substrate.

### BRIEF DESCRIPTION OF THE DRAWINGS

The objects and features of the present invention will become apparent from the following description of embodiments, given in conjunction with the accompanying drawings, in which:

FIG. 1 is a horizontal cross-sectional view showing a schematic structure of a multi-chamber type substrate processing system in accordance with a first embodiment of the present invention;

FIG. 2 is a plan view showing a first example of the substrate transfer device;

FIG. 3 is a front view showing the first example of the substrate transfer device;

FIG. 4 is a diagram for explaining a driving state of the first example of the substrate transfer device;

FIG. 5 is a perspective view for explaining a pick of the first example of the substrate transfer device;

FIG. 6 is a diagram for explaining a preferred example of backside supporting pads of the pick of the first example of the substrate transfer device;

FIG. 7 is an exploded perspective view showing a configuration of the backside supporting pads of FIG. 6;

FIGS. 8A and 8B are respectively a perspective view and a cross-sectional view for explaining a preferred example of stopper pins of the pick of the first example of the substrate transfer device;

FIG. 9 is a cross-sectional view for explaining another preferred example of the stopper pins of the pick of the first example of the substrate transfer device;

FIG. 10 is a plan view showing an essential part of a second example of the substrate transfer device;

FIG. 11 is a diagram showing a clamping mechanism of the second example of the substrate transfer device;

FIGS. 12A and 12B are diagrams for explaining states of the clamping mechanism and a multi-joint arm mechanism at the beginning and at the completion of the clamp by the clamping mechanism in the second example of the substrate transfer device, respectively;

FIG. 13 is a diagram showing a relationship between a capture range and a stroke of the multi-joint arm mechanism in the second example of the substrate transfer device;

FIGS. 14A and 14B are diagrams showing a velocity/acceleration curve and release timing when extending the multi-joint arm mechanism and a velocity/acceleration curve and clamp timing when retracting the multi-joint arm mechanism in the second example of the substrate transfer device, respectively;

FIG. 15 is a diagram for explaining a state of displacement due to thermal expansion when the wafer is held by the pick of the substrate transfer device;

FIG. 16 is a flowchart showing the procedure of correction of positional deviation due to thermal expansion in the substrate transfer device;

FIG. 17 a diagram for explaining a case of measuring the position of the wafer by the sensors in the correction of positional deviation due to thermal expansion;

FIG. 18 is a diagram for explaining a case of actually correcting the amount of deviation in the correction of positional deviation due to thermal expansion;

FIGS. 19A and 19B are diagrams for explaining the measurement of the reference position of the wafer and the calculation of the amount of deviation of the wafer, respectively;

FIG. 20A illustrates a velocity/acceleration curve and regions where the optical sensors can be installed in the first and second examples of the substrate transfer device when extending the multi-joint arm mechanism and FIG. 20B illustrates a velocity/acceleration curve and regions where the optical sensors can be installed in the first and second examples of the substrate transfer device when retracting the multi-joint arm mechanism;

FIG. 21 is a diagram showing a correlation between the extension measured by a laser displacement meter being used in correction of extension of the arm mechanism and the measurement results of the position detection sensor unit;

FIG. 22 is a diagram showing a relationship between the extension measured by the laser displacement meter and the temperature of the arm mechanism; and

FIG. 23 is a diagram showing a relationship between the extension measured by the laser displacement meter and idling time.

### DETAILED DESCRIPTION OF THE EMBODIMENTS

Hereinafter, embodiments of the present invention will be described in detail with reference to the accompanying drawings which forms a part hereof.

(Substrate Processing System of First Embodiment)

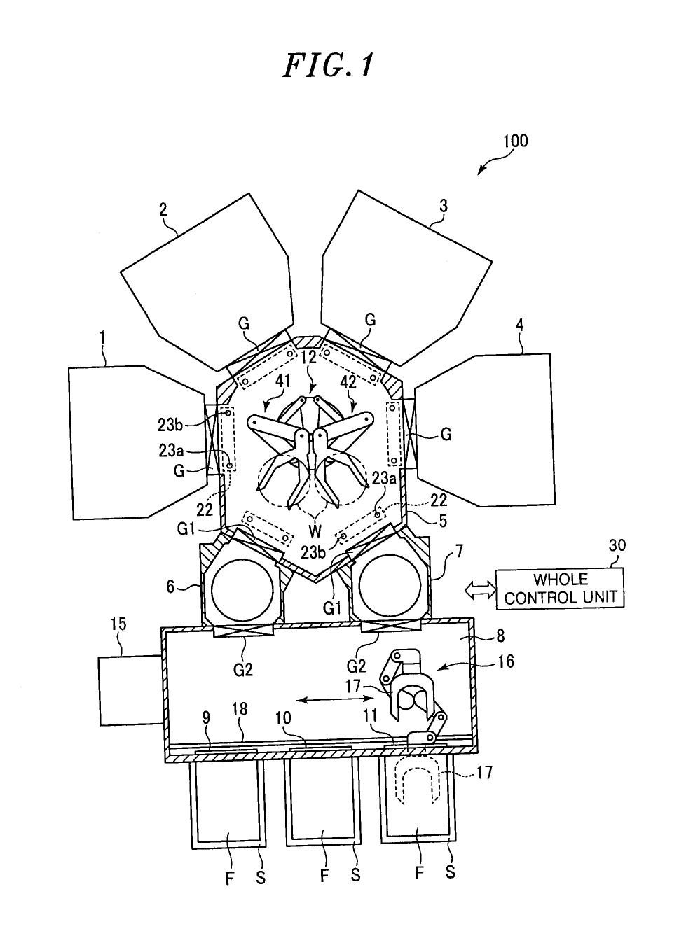

FIG. 1 is a horizontal cross-sectional view showing a schematic structure of a multi-chamber type substrate processing system in accordance with a first embodiment of the present invention.

A substrate processing system 100 includes four vacuum processing units 1, 2, 3 and 4 performing a high temperature process, such as a film formation process, accompanied by heat. The vacuum processing units 1 to 4 are respectively provided corresponding to four sides of a hexagonal transfer chamber 5. In addition, load-lock chambers 6 and 7 in accordance with this embodiment are respectively provided at the other two sides of the transfer chamber 5. A loading/unloading chamber 8 is provided at the sides of the load-lock chambers 6 and 7 opposite to the transfer chamber 5. At the side of the loading/unloading chamber 8 opposite to the load-lock chambers 6 and 7, three ports 9, 10 and 11 to which FOUPs F serving as containers accommodating substrates to be processed, i.e., wafers W, are attached are provided. The vacuum processing units 1, 2, 3 and 4 are configured to perform a specific vacuum process, e.g., etching or film formation, while an object to be processed is mounted on a processing plate therein.

Each of the vacuum processing units 1 to 4 is connected to the side of the transfer chamber 5 via a gate valve G as shown in FIG. 1. Each of the vacuum processing units 1 to 4 is communicated with the transfer chamber 5 by opening the corresponding gate valve G, and isolated from the transfer chamber 5 by closing the corresponding gate valve G. Further, the load-lock chambers 6 and 7 are respectively connected to the remaining sides of the transfer chamber 5 via first gate valves G1, and also connected to the loading/unloading chamber 8 via second gate valves G2. The load-lock chambers 6 and 7 have stages on which the wafers W are mounted, and can be changed at a high speed between an atmospheric pressure and a vacuum state. The load-lock chambers 6 and 7 are communicated with the transfer chamber 5 by opening the first gate valves G1 in the vacuum state, and isolated from the transfer chamber 5 by closing the first gate valves G1. Further, the load-lock chambers 6 and 7 are communicated with the loading/unloading chamber 8 by opening the second gate valves G2, and isolated from the loading/unloading chamber 8 by closing the second gate valves G2.

In the transfer chamber 5, a substrate transfer device 12 in accordance with this embodiment is provided to perform loading/unloading of the wafer W to/from the vacuum processing units 1 to 4 and the load-lock chambers 6 and 7. The substrate transfer device 12 is disposed substantially at the center of the transfer chamber 5, and has two multi-joint arm mechanisms 41 and 42. A detailed structure of the substrate transfer device 12 will be described later.

Shutters (not shown) are respectively provided at the ports 9, 10 and 11 of the loading/unloading chamber 8. The FOUPs F, each accommodating the wafers W or being empty, are directly attached to the ports 9, 10 and 11 while being mounted on stages S. When the FOUPs F are attached to the ports 9, 10 and 11, the shutters are opened such that the FOUPs F can communicate with the loading/unloading chamber 8 while preventing infiltration of outside air. Further, an alignment chamber 15 is provided on the side of the loading/unloading chamber 8 to perform an alignment of the wafer W.

A position detection sensor unit 22 is provided at a position where the wafer W to be loaded/unloaded passes by in the transfer chamber 5 in the vicinity of a loading/unloading port of each of the vacuum processing units 1 to 4 and the load-lock chambers 6 and 7. The position detection sensor unit 22 is intended to detect the position of the wafer W mounted on the multi-joint arm mechanisms 41 and 42 of the substrate transfer device 12. The position detection sensor unit 22 has two optical sensors 23a and 23b. As the optical sensors 23a and 23b, for example, transmissive type sensors are used.

In the loading/unloading chamber 8, a substrate transfer device 16 is provided to perform loading/unloading of the wafer W to/from the FOUPs F and the load-lock chambers 6 and 7. The substrate transfer device 16 has a multi-joint arm structure, and is movable on a rail 18 along an arrangement direction of the FOUPs F. The substrate transfer device 16 performs the transfer of the wafer W while the wafer W is held on a support arm 17 of its tip. The loading/unloading chamber 8 is configured such that a downflow of clean air is formed therein.

Each component in this substrate processing system 100, e.g., a gas supply system or exhaust system in the vacuum processing units 1 to 4, the transfer chamber 5 and the load-lock chambers 6 and 7, the substrate transfer devices 12 and 16, the gate valves and the like, is controlled by a whole control unit 30 having a controller with a microprocessor (computer). The whole control unit 30 includes, in addition to the controller actually performing the control, a storage unit storing process recipes as control parameters and process sequences of the substrate processing system 100, an input means, a display and the like, and configured to control the substrate processing system 100 in accordance with the selected process recipe.

(First Example of Substrate Transfer Device)

Next, a first example of the substrate transfer device mounted on the processing system will be described.

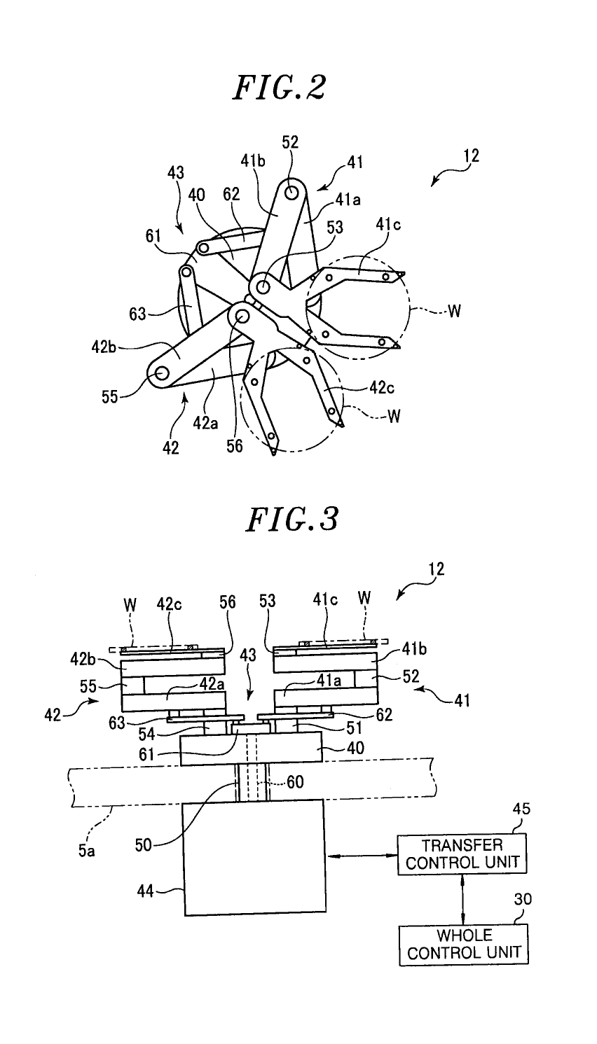

FIG. 2 is a plan view showing a first example of the substrate transfer device, and FIG. 3 is a front view thereof. The substrate transfer device 12 includes a rotational base 40 which is rotatably supported on a bottom plate 5a of the transfer chamber 5 serving as a base, a first multi-joint arm mechanism 41 and a second multi-joint arm mechanism 42 which are supported on the rotational base to be rotatable and extensible/contractible and have picks 41c and 42c to hold the wafer W, a drive link mechanism 43 which selectively extends or contracts one of the first multi-joint arm mechanism 41 and the second multi-joint arm mechanism 42, a drive unit 44 having a drive mechanism to rotate the rotational base 40 and a drive mechanism to swing the drive link mechanism 43, and a transfer control unit 45 which performs the control of the transfer operation. The transfer control unit 45 is controlled by the whole control unit 30. Each drive mechanism of the drive unit 44 is provided with a stepping motor being controlled by the number of pulses at an angle.

The rotational base 40 is rotated via a hollow shaft 50 by the drive mechanism of the drive unit 44. By rotating the rotational base 40, the first multi-joint arm mechanism 41 and the second multi-joint arm mechanism 42 are allowed to have access to a desired unit.

The first multi-joint arm mechanism 41 includes a first arm 41a whose base end portion is pivotably connected to the rotational base 40 by a shaft 51, a second arm 41b whose base end portion is pivotably connected to a leading end portion of the first arm 41a by a shaft 52, and the pick 41c for holding the wafer W, whose base end portion is pivotably connected to a leading end portion of the second arm 41b by a shaft 53. A pulley having a predetermined diameter is fixed to each shaft, and a belt is passed over the pulley. The first arm 41a, the second arm 41b and the pick 41c are rotated at a predetermined rotation angle ratio, and the pick 41c is movable in a straight line with respect to the vacuum processing units 1 to 4 and the load-lock chambers 6 and 7. Accordingly, the wafer W can be loaded to and unloaded from the vacuum processing units 1 to 4 and the load-lock chambers 6 and 7.

The second multi-joint arm mechanism 42 has the same structure as the first multi-joint arm mechanism 41 and is arranged symmetrical with the first multi-joint arm mechanism 41. The second multi-joint arm mechanism 42 includes a first arm 42a whose base end portion is pivotably connected to the rotational base 40 by a shaft 54, a second arm 42b whose base end portion is pivotably connected to a leading end portion of the first arm 42a by the shaft 55, and the pick 42c for holding the wafer W, whose base end portion is pivotably connected to a leading end portion of the second arm 42b by a shaft 56. The second multi-joint arm mechanism 42 can operate in the same manner as the first multi-joint arm mechanism 41.

In other words, the substrate transfer device 12 is driven by the drive unit 44 via a mechanism portion of the drive link mechanism 43 and the multi-joint arm mechanisms 41 and 42 to allow the picks 41c and 42c to have access to the vacuum processing units 1 to 4 and the load-lock chambers 6 and 7. The wafer W can be loaded to and unloaded from the vacuum processing units 1 to 4 and the load-lock chambers 6 and 7 using the picks 41c and 42c.

The drive link mechanism 43 includes a drive arm 61 which is swingably provided via a shaft 60 disposed coaxially in the hollow shaft 50 by the drive mechanism of the drive unit 44, and two follower arms 62 and 63 having one-side ends rotatably connected to a leading end of the drive arm 61 and the other-side ends rotatably connected to a lower portion of the first arm 41a of the first multi-joint arm mechanism 41 and a lower portion of the first arm 42a of the second multi-joint arm mechanism 42. Then, by rotating the shaft 60 to swing the drive arm 61 forwardly and reversely via the belt and pulley (not shown), one of the first multi-joint arm mechanism 41 and the second multi-joint arm mechanism 42 can be extended and the other one can be bent. That is, one multi-joint arm mechanism is extended by swinging the drive arm 61 toward one side, and the other multi-joint arm mechanism is extended by swinging the drive arm 61 toward the other side.

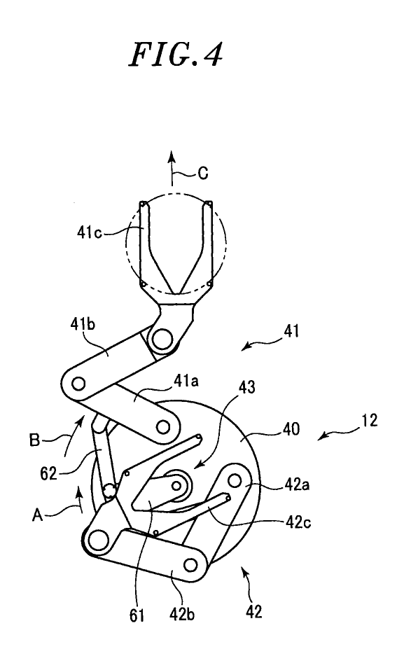

Specifically, as shown in FIG. 4, by swinging the drive arm 61 in the direction of arrow A, the first arm 41a of the first multi-joint arm mechanism 41 is rotated in the direction of arrow B, the first multi-joint arm mechanism 41 is extended, and the pick 41c is moved linearly in the direction of arrow C.

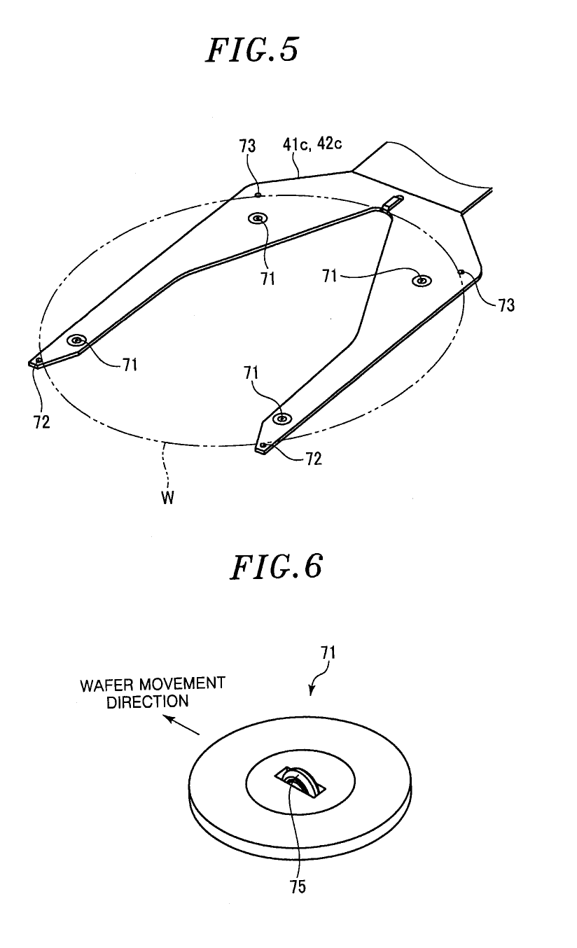

As shown in FIG. 5, each of the picks 41c and 42c has four backside supporting pads 71 for supporting the backside of the wafer W, two leading end side stopper pins 72 for supporting an end portion of the wafer W at the leading end side, and two base end side stopper pins 73 for supporting an end portion of the wafer W at the base end side. While the backside of the wafer W is supported by the backside supporting pads 71, the wafer W is interposed between the leading end side stopper pins 72 and the base end side stopper pins 73, and the wafer W is pressed against the leading end side stopper pins 72 by inertia when the multi-joint arm mechanism is extended, thereby positioning the wafer W on the picks 41c and 42c. That is, the two leading end side stopper pins function as positioning pins. Accordingly, it is possible to maintain high accuracy of the position of the wafer W on picks 41c and 42c even if the wafer W is transferred at a high speed.

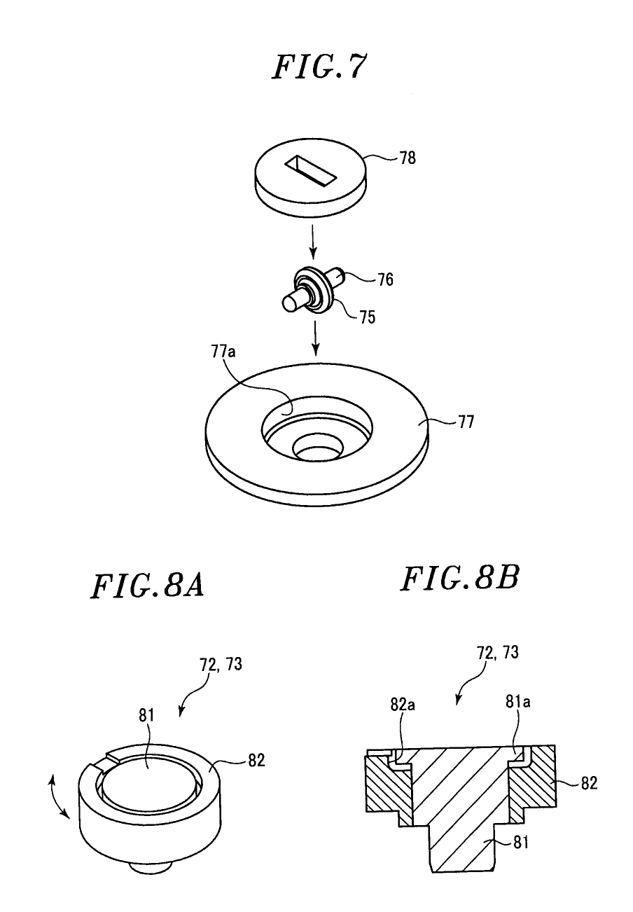

In this way, since positioning of the wafer W is performed on the picks 41c and 42c by pressing the wafer W against the leading end side stopper pins 72 by inertia when the multi-joint arm mechanism is extended, it is preferable that the backside supporting pads 71 have a structure in which the wafer W on the backside supporting pads 71 is easy to move in terms of improving the positional accuracy (position reproducibility). Accordingly, slippery objects, e.g., carbon spheres composed of only carbon having self-lubricity, may be used in a fixed state. However, since the position reproducibility is lowered in vacuum due to an increase in coefficient of friction, it is preferable to use roller pads having rollers (pulleys) 75 rolling to allow the wafer W to move in the direction of inertia as shown in FIG. 6. In this case, each of the backside supporting pads 71 is configured such that, as shown in FIG. 7, the roller 75 to which a rotation shaft 76 is attached is inserted into a recess portion 77a of a receiving member 77, and the recess portion 77a is covered with a lid 78 in order to hold the rotation shaft 76 to allow the roller 75 to rotatably protrude from the lid 78. The roller 75, the receiving member 77 configured to receive the roller, and the lid 78 are preferably formed of hard resin (e.g., polybenzimidazole (PBI) resin).

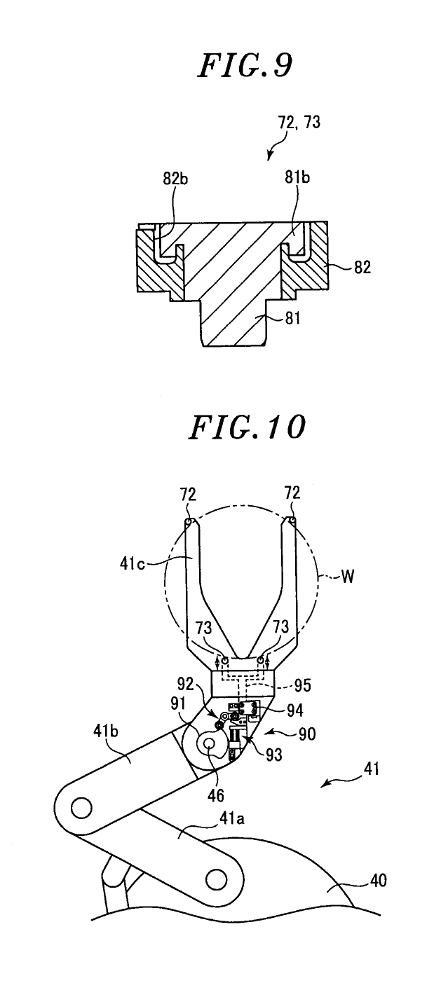

The leading end side stopper pins 72 and the base end side stopper pins 73 are preferably formed of a material with small friction to hardly generate the dust, e.g., PBI resin. However, even though the material hardly generating the dust is used, the friction between the wafer W and the stopper pins 72 and 73 increases when the wafer temperature increases and, thus, the dust might be generated when the wafer W is in contact with and rubs against them to generate particles. Accordingly, it is preferable that the leading end side stopper pins 72 and the base end side stopper pins 73 have a structure including, as shown in FIG. 8, a core portion 81 of a cylindrical shape which is fixed vertically to the pick and a ring member 82 which is rotatably configured to be loosely fitted on the outside. Accordingly, since the ring member 82 is rotated when the wafer W is brought into contact with the stopper pins 72 and 73, a tangential force may decrease and the dust generation due to friction can be reduced. In the example shown in FIGS. 8A and 8B, a groove 82a is formed at an inner periphery of an upper portion of the ring member 82, and a flange 81a is provided at the top of the core portion 81 so that the flange 81a is engaged with the groove 82a. As shown in FIG. 9, a groove 82b may be formed at the inner periphery of the upper portion of the ring member 82, and a flange 81b may be formed at the top of the core portion 81 such that an engagement portion of the ring member 82 and the core portion 81 has a labyrinth structure. By forming this labyrinth structure, there is an advantage that particles generated due to abrasion of the ring member 82 and the core portion 81 are less likely to scatter.

The transfer control unit 45 not only controls the transfer operation of the wafer W in the substrate transfer device 12 by controlling the drive mechanism of the drive unit 44, but also corrects a positional deviation of the wafer W due to thermal expansion. In this embodiment, in order to perform the positioning of the wafer W in the picks 41c and 42c, if a process accompanied by heat is performed in the vacuum processing units 1, 2, 3 and 4, when the arm or pick of the multi-joint arm mechanisms 41 and 42 expands due to heat from the wafer W or chamber of these units, a center position of the wafer W is deviated from its original position. For this reason, a reference position of the wafer W is measured by using the optical sensors 23a and 23b of the position detection sensor unit 22 provided in the vicinity of the loading/unloading port of each of the vacuum processing units 1 to 4 and the load-lock chambers 6 and 7, and stored in the transfer control unit 45. Then, when actually loading the wafer W into any of the vacuum processing units 1 to 4 and the load-lock chambers 6 and 7, the position of the wafer W is measured by using the optical sensors 23a and 23b of the position detection sensor unit 22, and the transfer control unit 45 compares the measurement results with information on the stored reference position and perceives the amount of deviation of the wafer W to control such that the loading is performed to correct the amount of deviation.

(Second Example of Substrate Transfer Device)

Next, a second example of the substrate transfer device mounted on the processing system will be described.

In the first example of the substrate transfer device, the positioning of the wafer W is performed on the picks 41c and 42c by pressing the wafer W against the leading end side stopper pins 72 by inertia when the multi-joint arm mechanism is extended while the wafer W is interposed between the leading end side stopper pins 72 and the base end side stopper pins 73. However, if the transfer speed is faster, there is concern about the generation of particles when the wafer W is brought into contact with the leading end side stopper pins 72, the misalignment of the wafer W when rotating the multi-joint arm mechanisms 41 and 42, or the positional deviation of the wafer W in the measurement using the position detection sensor unit 22.

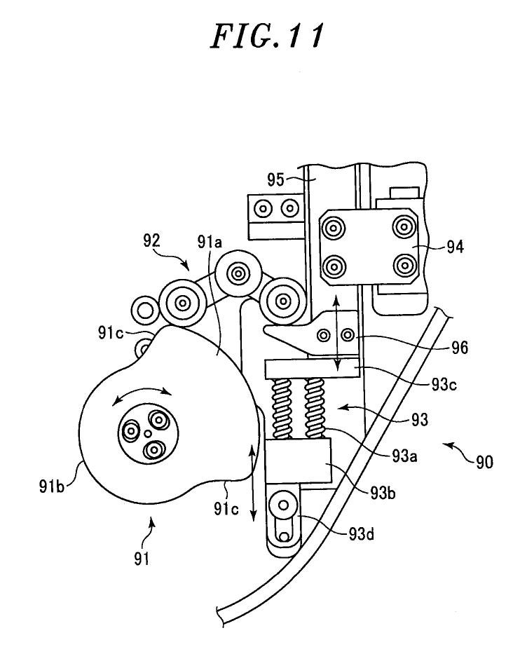

For this reason, in this example, as shown in FIG. 10 and FIG. 11 that is an enlarged view of FIG. 10, a clamping mechanism 90 is further provided to clamp the wafer W after placing the wafer W between the leading end side stopper pins 72 and the base end side stopper pins 73 of the picks 41c and 42c of the first multi-joint arm mechanism 41 and the second multi-joint arm mechanism 42 of the first example. The other configuration is the same as the substrate transfer device of the first example. In the following description, for convenience, an explanation will be made with regard to only the pick 41c of the first multi-joint arm mechanism 41, but the same is true for the second multi-joint arm mechanism 42.

The clamping mechanism 90 is intended to clamp the wafer W by the displacement of a cam caused by the rotation of the pick 41c by using a rotation mechanism of the pick 41c. The clamping mechanism 90 includes a cam 91 attached to a rotation shaft 46 of the pick 41c, an extensible/contractible member 93 which extends or contracts by the displacement of the cam 91, a link mechanism 92 which transmits the displacement of the cam 91 to the extensible/contractible member 93, a moving member 95 which moves the base end side stopper pins 73 back and forth by the extension and contraction of the extensible/contractible member 93 to perform or cancel clamping of the wafer W, and a linear guide 94 which guides the moving member 95. Further, a capture range adjustment member 96 is provided between the link mechanism 92 and the extensible/contractible member 93 to adjust a capture range.

The extensible/contractible member 93 includes a coil spring 93a, a spring fixing block 93b, a moving block 93c, and a position adjustment portion 93d which adjusts a spring force by adjusting the position of the spring fixing block 93b. The moving member 95 is pressed via the moving block 93c and the capture range adjustment member 96 by a biasing force of the coil spring 93a, and the moving member 95 presses the base end side stopper pins 73 to clamp the end portion of the wafer W.

The cam 91 is configured to rotate relative to the pick 41c when the pick 41c rotates relative to the second arm 41b by the rotation mechanism during the operation of the first multi-joint arm mechanism 41. The cam 91 has a large diameter portion 91a pressing the link mechanism 92, a small diameter portion 91b not pressing the link mechanism 92, and an inclined portion 91c formed between them.

Further, if the large diameter portion 91a of the cam is located at a position corresponding to the link mechanism 92, the cam 91 presses the link mechanism 92 to press the moving block 93c of the extensible/contractible member 93 via the capture range adjustment member 96. Then, the base end side stopper pins 73 are retracted along with the moving member 95 so that the wafer W can be received and delivered. Further, in a case where the small diameter portion 91b of the cam 91 is located at a position corresponding to the link mechanism 92, without pressing the link mechanism 92, as described above, the moving member 95 presses the base end side stopper pins 73 to clamp the end portion of the wafer W. In addition, when the inclined portion 91c corresponds to the link mechanism 92, the base end side stopper pins 73 are moved in the clamp direction or retraction direction.

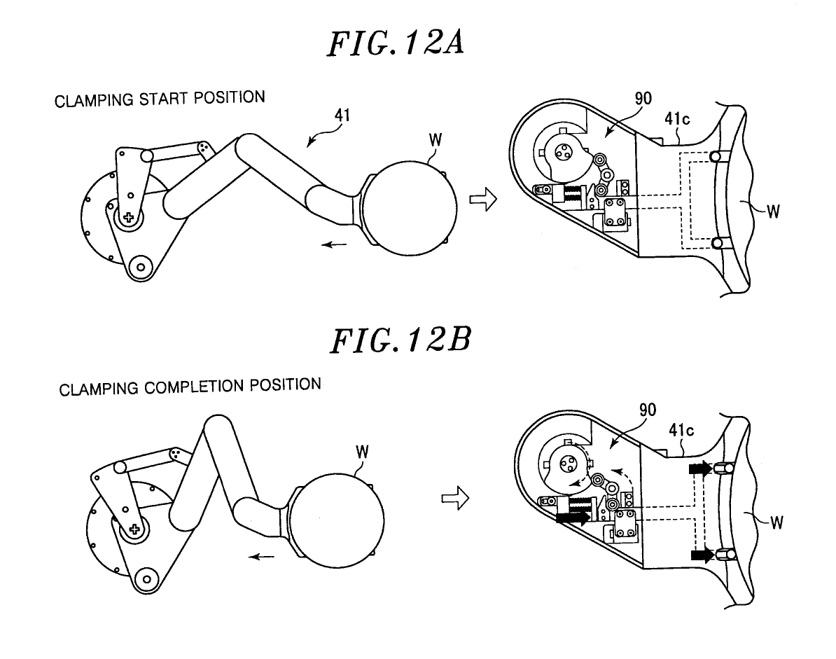

The position of the cam 91 is adjusted such that the positions of the base end side stopper pins 73 are determined in synchronization with the position of the pick 41c of the first multi-joint arm mechanism 41. For example, if the clamping is performed after receiving the wafer W, while the first multi-joint arm mechanism 41 receiving the wafer W is extended, the cam 91 is located at a position for pressing the link mechanism 92 by the large diameter portion 91a to press the extensible/contractible member 93 through the link mechanism 92 such that the base end side stopper pins 73 are retracted by the moving member 95. After receiving the wafer W, while the first multi-joint arm mechanism 41 is retracted, as shown in FIG. 12A, the position of the cam 91 corresponding to the link mechanism 92 reaches an end portion of the large diameter portion 91a and clamping of the wafer W is started at that point. The first multi-joint arm mechanism 41 is further retracted, and the clamping of the wafer W is completed when the position of the cam 91 corresponding to the link mechanism 92 reaches the small diameter portion 91b through the inclined portion 91c as shown in FIG. 12B. When the wafer W can be delivered by releasing the clamp of the wafer W, the opposite movement is carried out.

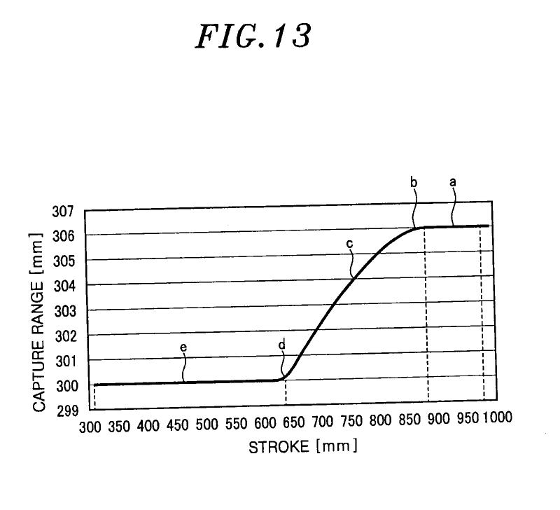

FIG. 13 shows a relationship between the capture range by the clamping mechanism 90 and the stroke of the first multi-joint arm mechanism 41 in this case. The capture range refers to a length from pressing portions of the base end side stopper pins 73 to the opposite end portion of the wafer W. In this example, the diameter of the wafer W is 300 mm, the capture range when clamping the wafer W is 300 mm, and the capture range when releasing the wafer W is 306 mm. In addition, the stroke of the first multi-joint arm mechanism 41 is a distance between the center of the rotational base 40 (the center of the shaft 60) and the center of the wafer W on the pick 41c. The stroke when the first multi-joint arm mechanism 41 is retracted maximally is 308 mm and the stroke when the first multi-joint arm mechanism 41 is extended maximally is 980 mm.

At the time of clamping the wafer W, ‘a’ of FIG. 13 is a range of receiving the wafer W in which the cam 91 is located at a position where the large diameter portion 91a presses the link mechanism 92 and the capture range is a maximum of 306 mm. Further, ‘b’ is a start position of clamping where the position of the cam 91 corresponding to the link mechanism 92 is moved to the inclined portion 91c from the large diameter portion 91a. Further, ‘c’ is a range of performing the clamping operation of the wafer W in which the position of the cam 91 corresponding to the link mechanism 92 is the inclined portion 91c and the capture range is decreasing. Further, ‘d’ is an end position of clamping where the position of the cam 91 corresponding to the link mechanism 92 is moved to the small diameter portion 91b from the inclined portion 91c and the capture range is 300 mm. Further, ‘e’ is a range of further reducing the stroke in which the position of the cam 91 corresponding to the link mechanism 92 is the small diameter portion 91b and the wafer W is clamped.

At the time of releasing the wafer W, it becomes opposite. When reaching ‘d’ from ‘e’ of the clamp state, it is a start position of releasing where the position of the cam 91 corresponding to the link mechanism 92 is moved to the inclined portion 91c from the small diameter portion 91b. Further, ‘c’ is a range of performing the releasing operation of the wafer W in which the capture range is increasing, and ‘b’ is an end position of releasing. Further, in a range of ‘a’, the delivery of the wafer W is performed.

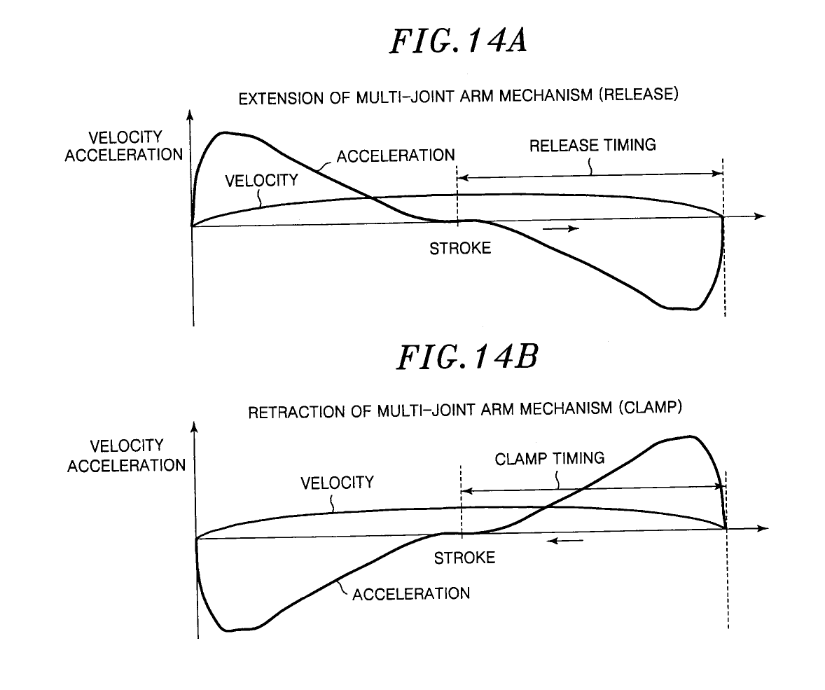

FIGS. 14A and 14B show a velocity/acceleration curve when extending the first multi-joint arm mechanism 41 (releasing the wafer W) and a velocity/acceleration curve when retracting the first multi-joint arm mechanism 41 (clamping the wafer W). As shown in FIG. 14A, when the first multi-joint arm mechanism 41 is extended to release the wafer W, a range in which the stroke of the first multi-joint arm mechanism 41 is long is a region in which the acceleration is negative, i.e., a deceleration region. During the extension, since the wafer W is pressed against the leading end side stopper pins 72 in the region in which the acceleration is negative, it is desirable that that the clamping of the wafer W is canceled (the wafer W is released) in this range. Further, as shown in FIG. 14B, when the first multi-joint arm mechanism 41 is retracted to clamp the wafer W, a range in which the stroke of the first multi-joint arm mechanism 41 is long is a region in which the acceleration is positive, i.e., an acceleration region. During the retraction, since the wafer W is pressed against the leading end side stopper pins 72 in the region in which the acceleration is positive, it is desirable that the wafer W is clamped in this range. In this way, when the wafer W is pressed against the leading end side stopper pins 72, even if the clamping is performed or canceled, the wafer W is not moved and it does not cause degradation of the positional accuracy or the like.

Also in this second example, in the same manner as the first example, the transfer control unit 45 not only controls the transfer operation of the wafer W in the substrate transfer device 12 by controlling the drive mechanism of the drive unit 44, but also corrects the positional deviation of the wafer W due to thermal expansion.

(Operation of Substrate Processing System)

Next, the operation of the substrate processing system 100 will be described.

First, the wafer W is unloaded from the FOUP F connected to the loading/unloading chamber 8 and loaded into the load-lock chamber 6 (or 7) by the substrate transfer device 16. At this time, the wafer W is loaded in a state where the second gate valve G2 is opened after an air atmosphere is formed in the load-lock chamber 6 (or 7).

Then, the load-lock chamber 6 (or 7) is evacuated to a pressure corresponding to the transfer chamber 5, and the first gate valve G1 is opened. Then, the wafer W in the load-lock chamber 6 (or 7) is carried by using the first multi-joint arm mechanism 41 or the second multi-joint arm mechanism 42 of the substrate transfer device 12 and loaded into any one vacuum processing unit after opening the gate valve G thereof. A vacuum process accompanied by heat such as film formation is performed on the wafer W.

When the vacuum process is completed, the gate valve G is opened, and the wafer W is unloaded from the corresponding vacuum processing unit by the substrate transfer device 12. Then, the first gate valve G1 is opened, and the wafer W is unloaded into any one of the load-lock chambers 6 and 7 such that it returns to the atmospheric pressure while cooling the wafer W. Then, the second gate valve G2 is opened, and the processed wafer W is accommodated in the FOUP F by the substrate transfer device 16. This operation is repeated as many as the number of the wafers W in the FOUPs F.

At this time, in case of using the substrate transfer device of the first example as the substrate transfer device 12, the picks 41c and 42c of the first multi-joint arm mechanism 41 and the second multi-joint arm mechanism 42 holding the wafer W during the transfer of the wafer W have the leading end side stopper pins 72 and the base end side stopper pins 73, and the wafer W is interposed between the stopper pins 72 and 73. Then, the wafer W is positioned on the picks 41c and 42c by pressing the wafer W against the leading end side stopper pins 72 by inertia when extending the multi-joint arm mechanism. For this reason, even if the wafer W is transferred at a high speed, the wafer W is prevented from slipping on the picks 41c and 42c, and it is possible to maintain high positional accuracy of the wafer. In addition, even though the stopper pins 72 and 73 (the core portion 81 or ring member 82) are abraded, the wafer W is positioned on the picks 41c and 42c by pressing the wafer W against the leading end side stopper pins 72.

As described above, in the case where the wafer W is positioned by pressing the wafer W against the leading end side stopper pins 72 by inertia when extending the multi-joint arm mechanism, it is required for the wafer W to move on the backside supporting pads 71. By forming the backside supporting pads 71 using a material having good lubricity such as carbon spheres, some degree of positional accuracy is obtained, but in case of transferring the wafer W in the vacuum as in this embodiment, even if the material has good lubricity at a normal pressure, the friction increases. In contrast, by using the roller pads having the rollers (pulleys) 75 rolling in the direction in which the wafer W moves by inertia as shown in FIG. 6, the wafer W is easy to move even in the vacuum, and it is possible to performing positioning of the wafer W with high accuracy.

Also, in the configuration in which the picks 41c and 42c hold the wafer W by using the leading end side stopper pins 72 and the base end side stopper pins 73, when the wafer W has a high temperature as in this embodiment, even though the material hardly generating the dust is used for the stopper pins 72 and 73, the friction between the wafer W and the stopper pins 72 and 73 becomes large due to an increase in the temperature of the wafer and, thus, the dust might be generated when the wafer W is in contact with and rubs against them to generate particles. However, as shown in FIGS. 8A to 9 described above, by providing the rotatable ring member 82 at the outer peripheral side, the tangential force may decrease and the dust generation due to friction can be reduced.

In the first example of the substrate transfer device, the positioning of the wafer W is performed on the picks 41c and 42c by pressing the wafer W against the leading end side stopper pins 72 by inertia when the multi-joint arm mechanism is extended while the wafer W is interposed between the leading end side stopper pins 72 and the base end side stopper pins 73. However, since the wafer W is movable between the leading end side stopper pins 72 and the base end side stopper pins 73, if the transfer speed is faster, there is concern about the generation of particles when the wafer W is brought into contact with the leading end side stopper pins 72, or the misalignment of the wafer W when rotating the multi-joint arm mechanisms 41 and 42.

Therefore, in the second example of the substrate transfer device, after the wafer W is interposed between the leading end side stopper pins 72 and the base end side stopper pins 73, the wafer W is clamped by pressing the base end side stopper pins 73 against the wafer W by using the clamping mechanism 90.

In this manner, by clamping the wafer W, it is possible to prevent the wafer W from being brought into contact with the leading end side stopper pins 72 even if the transfer speed is even faster, and to effectively prevent the generation of particles. In addition, it is possible to prevent the misalignment of the wafer W when rotating the multi-joint arm mechanisms 41 and 42.

As described above, if the first multi-joint arm mechanism 41 is mentioned as an example, the clamping mechanism 90 is used to clamp the wafer W by the displacement of the cam 91 caused by the rotation of the pick 41c. The position of the cam 91 is adjusted such that the forward/backward movement of the base end side stopper pins 73 is determined in synchronization with the rotational position of the pick 41c of the first multi-joint arm mechanism 41. Specifically, if the clamping is performed during the retraction after receiving the wafer W, in the state where the first multi-joint arm mechanism 41 to receive the wafer W is extended, the cam 91 is located at a position where the link mechanism 92 is pressed by the large diameter portion 91a to press the extensible/contractible member 93 via the link mechanism 92, and the base end side stopper pins 73 are retracted. After receiving the wafer W, while the first multi-joint arm mechanism 41 is retracted, the position of the cam 91 corresponding to the link mechanism 92 reaches the end portion of the large diameter portion 91a and clamping of the wafer W is started at that point. The first multi-joint arm mechanism 41 is further retracted, and the clamping of the wafer W is completed when the position of the cam 91 corresponding to the link mechanism 92 reaches the small diameter portion 91b through the inclined portion 91c (see FIGS. 12A and 12B). When the wafer W can be delivered by releasing the clamp of the wafer W, the opposite movement is carried out.

In this way, by employing the clamping mechanism 90 using the cam 91 and the rotation mechanism of the pick 41c, since the wafer W is clamped or clamping is canceled by the operation of the cam 91 caused by the rotation of the pick 41c, there is no need for a control mechanism or special power for the clamp, and it is possible to scale down the size of facilities. In addition, as described above, since the wafer W is clamped by the clamping mechanism 90 while the wafer W is placed between the leading end side stopper pins 72 and the base end side stopper pins 73, the capture range before clamping can be greater than that in the substrate transfer device of the first example to thereby facilitate the receipt and delivery of the wafer W.

Also, when releasing the wafer W by extending the first multi-joint arm mechanism 41, the clamping of the wafer W is canceled (the wafer W is released) in a region (i.e., a deceleration region) where the acceleration is negative in a range in which the first multi-joint arm mechanism 41 has a long stroke. Further, when clamping the wafer W by retracting the first multi-joint arm mechanism 41, the wafer W is clamped in a region (i.e., an acceleration region) where the acceleration is positive in a range in which the first multi-joint arm mechanism 41 has a long stroke. Accordingly, the wafer W can be clamped or the clamping can be canceled in the state where the wafer w is pressed against the leading end side stopper pins 72. Thus, when the clamping of the wafer W is performed or canceled, the wafer W is not moved and it does not cause degradation of the positional accuracy or the like.

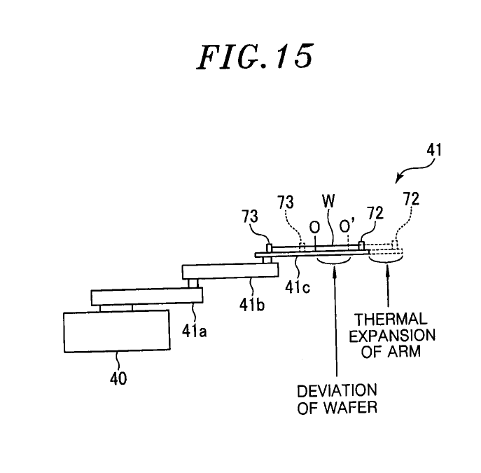

However, in the substrate transfer device of any of the first and second examples, if it is configured such that the pick 41c (or 42c) holds the wafer W by using the leading end side stopper pins 72 and the base end side stopper pins 73, as schematically shown in FIG. 15, the wafer W is positioned by the pick 41c (or 42c). Accordingly, if the arm or pick of the multi-joint arm mechanisms 41 and 42 thermally expands due to heat of the vacuum processing units 1 to 4, the position of the wafer W is displaced by the thermal expansion. In this way, when the wafer W is transferred to the vacuum processing units 1 to 4 or the load-lock chambers 6 and 7 while the position of the wafer W is deviated, the wafer W is placed at a position deviated from a predetermined position on the stage.

Therefore, in this embodiment, in order that the wafer W is transferred to an accurate position, the correction of positional deviation due to thermal expansion is performed in the following procedure.

(Correction of Positional Deviation of Wafer Due to Thermal Expansion)

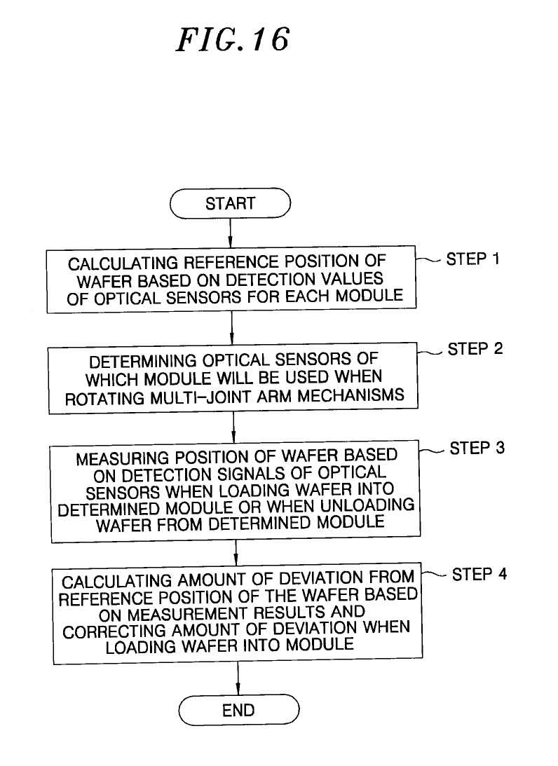

The correction of positional deviation due to thermal expansion can be carried out in the procedure in a flowchart of FIG. 16.

First, for each module of the vacuum processing units 1 to 4 and the load-lock chambers 6 and 7, the reference position of the wafer is calculated based on detection values of the optical sensors 23a and 23b of the corresponding position detection sensor unit 22, and stored in the transfer control unit 45 (step 1).

In the actual transfer of the wafer W, it is determined the optical sensors 23a and 23b of which module will be used when rotating the first and second multi-joint arm mechanisms 41 and 42 of the substrate transfer device 12 (step 2).

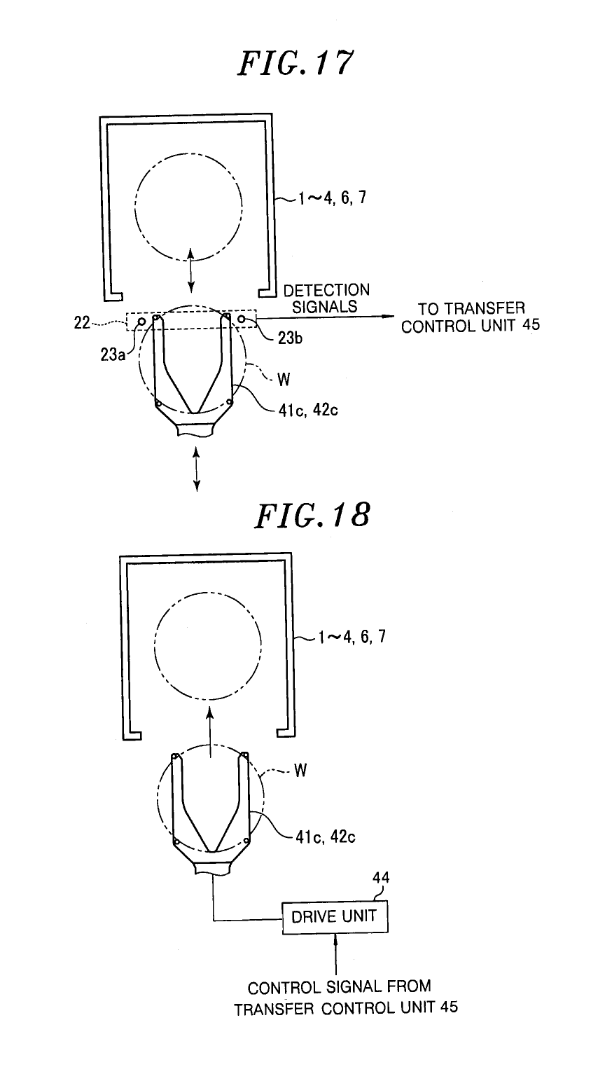

As shown in FIG. 17, when the wafer W is loaded into the module (any of the vacuum processing units 1 to 4 and the load-lock chambers 6 and 7), or when the wafer W is unloaded to the transfer chamber 5 from the module, the position of the wafer W is measured by the transfer control unit 45 based on detection signals of the optical sensors 23a and 23b (step 3).

The transfer control unit 45 calculates the amount of deviation from the reference position of the wafer W based on the measurement results, and as shown in FIG. 18, controls the drive unit 44 of the substrate transfer device 12 to correct the amount of deviation when the wafer W is loaded into the module (step 4).

Next, a method of measuring the reference position of the wafer W and calculating the amount of deviation will be described in detail. Since each drive mechanism of the drive unit 44 uses a stepping motor, position information can be grasped by a pulse value.

[Measurement of Reference Position of Wafer]

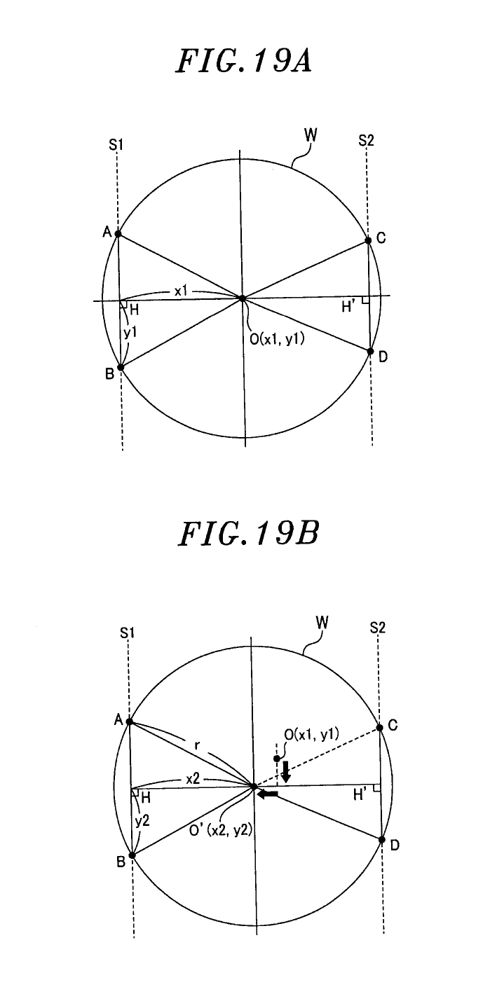

Measurement of the reference position of the wafer W is carried out at room temperature when the wafer W in the corresponding module is unloaded to the transfer chamber 5 while being on the mounted on the pick. At this time, the pick holding the wafer W is moved in a linear fashion. As shown in FIG. 19A, points at which the wafer W shields the light irradiated from optical sensors S1 and S2 are referred to as A and C, and points at which the wafer W is moved to transmit the light irradiated from the optical sensors S1 and S2 are referred to as B and D. As a value known in advance, the reference wafer radius is 150 mm.

(a) Calculation Procedure of Distance HH′ between Sensors

First, under these conditions, a distance HH′ between the sensors is calculated in the following steps 1 to 5:

1. Convert the pulse value of A-D into an actual position of the arm

2. Calculate the lengths of AB and CD

3. Calculate the length of OH from OH²=AO²−(AB÷2)² which is an equation established by Pythagorean theorem

4. Calculate the length of OH′ in the same manner as in steps 1 to 3

5. Calculate the length of HH′ from HH′=OH+OH′ obtained from steps 3 and 4

(b) Calculation Procedure of Coordinates of Reference Wafer Position O

Next, coordinates (x1, y1) of the reference wafer position O are calculated in the following steps 6 to 8:

6. Set S1 as a reference (X=0) of X coordinates

7. Calculate X coordinate (x1) of the reference wafer position O from x1=OH because the length of OH has already been calculated in step 3.

8. Calculate Y coordinate (y1) of the reference wafer position O from y1=Position of Arm at B+(AB÷2)

[Calculation of Amount of Deviation of Wafer]

Calculation of the amount of deviation of the wafer W is carried out when the wafer W in the corresponding module is unloaded to the transfer chamber 5 while being on the mounted on the pick. At this time, in the same manner as in the measurement of the reference position, the pick holding the wafer W is moved in a linear fashion. As values known in advance, the distance HH′ between the sensors and the coordinates of the reference wafer position O are used. As shown in FIG. 19B, in the same manner as in the measurement of the reference position, points at which the wafer W shields the light irradiated from the optical sensors S1 and S2 are referred to as A and C, and points at which the wafer W is moved to transmit the light irradiated from the optical sensors S1 and S2 are referred to as B and D.

(a) Calculation Procedure of Wafer radius r and X Coordinate (x2) of Wafer Position O′

A wafer radius r and X coordinate (x2) of the wafer position O′ are calculated in the following steps 9 to 11:

9. Convert the pulse value of A-D into an actual position of the arm

10. Calculate the lengths of AB and CD

11. Calculate the wafer radius r and X coordinate (x2) from the following simultaneous equations established by Pythagorean theorem

r²=(x2)²+(AB÷2)²

r²=(HH′−x2)²+(CD÷2)²

(b) Calculation Procedure of Y Coordinate (y2) of Wafer Position O′

Y coordinate (y2) of the wafer position O′ is calculated in the following step 12:

12. Calculate Y coordinate (y2) of the wafer position O′ from y2=Position of Arm at B+(AB÷2)

(c) Calculation Procedure of Amount of Deviation of Wafer

The amount of deviation of the wafer is calculated in the following step 13:

13. Calculate the amount of deviation from the coordinates (x2, y2) of the wafer position O′ and the coordinates (x1, y1) of the reference position O in the following equation:

(Amount of Deviation)²=(x2−x1)²+(y2−y1)²

In this way, since the positioning of the wafer W is performed in the picks 41c and 42c and the position correction is carried out by using the sensors provided corresponding to each module, even if the position of the wafer W is deviated due to thermal expansion of the arm or pick, even thermal expansion of the wafer W, the wafer W can be transferred with high positional accuracy. In addition, the position correction of the wafer W can be performed even if the position of the wafer W is deviated due to factors other than the thermal expansion. For example, even if the stopper pins 72 and 73 (the core portion 81 or ring member 82) are abraded, the wafer W is positioned on the picks 41c and 42c by pressing the wafer W against the leading end side stopper pins 72, and the position correction can be performed by the above method. Further, as the amount of deviation is larger, it is possible to recognize the time to replace the pick or arm.

However, in the substrate transfer device of the first example, since there is a possibility for the wafer W to move on the picks 41c and 42c during deceleration, there is concern about the positional deviation of the wafer W in the measurement using the position detection sensor unit 22. In other words, in the first example, since the wafer W is pressed against any of the stopper pins in the region (i.e., acceleration region) where the acceleration is positive, if the optical sensors 23a and 23b of the position detection sensor unit 22 are installed in that region, the positional deviation of the wafer W does not occur substantially. However, if the optical sensors 23a and 23b of the position detection sensor unit 22 are installed in the region (i.e., deceleration region) where the acceleration is negative, since the measurement is made while the wafer W is moving, the error becomes large.

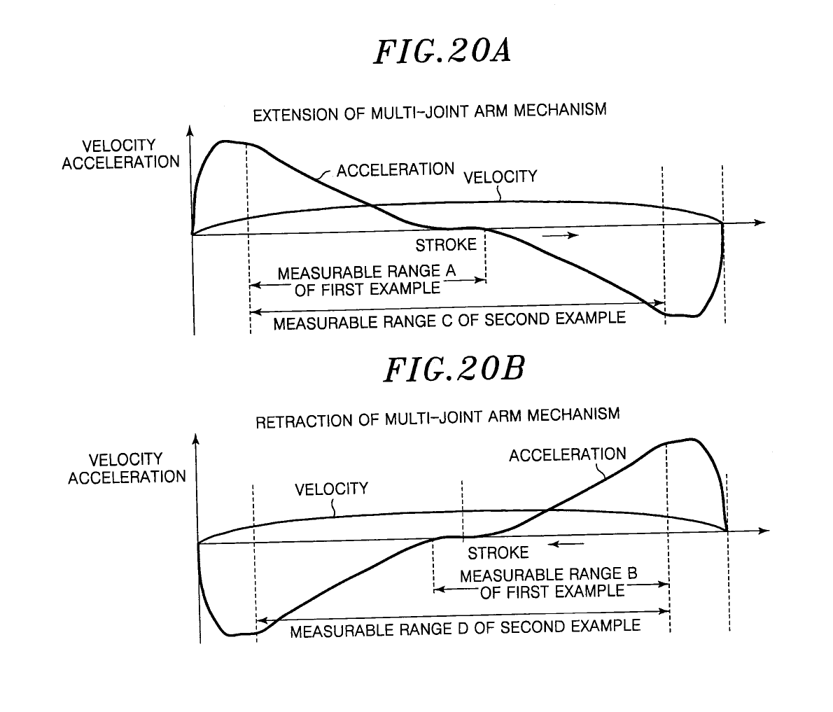

Specifically, in the extension of the multi-joint arm mechanism, i.e., if the wafer W is loaded into the module, as shown in FIG. 20A, the measurement can be made accurately only in range A in which the stroke of the multi-joint arm mechanism is short. Further, in the retraction of the multi-joint arm mechanism, i.e., if the wafer W is unloaded from the module, as shown in FIG. 20B, the measurement can be made accurately only in range B in which the stroke of the multi-joint arm mechanism is long. Therefore, it is difficult to accurately perform the measurement without causing the positional deviation of the wafer W both when transferring the wafer W to the module and when unloading the wafer W from the module by installing the optical sensors 23a and 23b at specific positions. Further, if there is a limit to the installation positions of the optical sensors 23a and 23b, in some cases, the measurement may not be made accurately.

On the other hand, in the second example of clamping the wafer W, the position of the wafer W can be measured accurately in range C of FIG. 20A, range D of FIG. 20B, and almost all regions when the wafer W is loaded into the module and unloaded from the module.

(Correction of Extension of Arm Mechanism)

Although it is possible to perform the correction of positional deviation of the wafer due to thermal expansion in the above procedure, in a case where the process is performed again after a long period of idling, the actual amount of extension of the arm or pick of the first multi-joint arm mechanism 41 and the second multi-joint arm mechanism 42 of the substrate transfer device 12 is uncertain. When the transfer operation is performed as it is based on data immediately before idling, when the wafer W is put on the pick, the wafer W might be seated on the leading end side stopper pins 72 or the base end side stopper pins 73. Accordingly, it is preferable to perform the correction of extension of the first multi-joint arm mechanism 41 and the second multi-joint arm mechanism 42 (hereinafter simply referred to the arm mechanism).

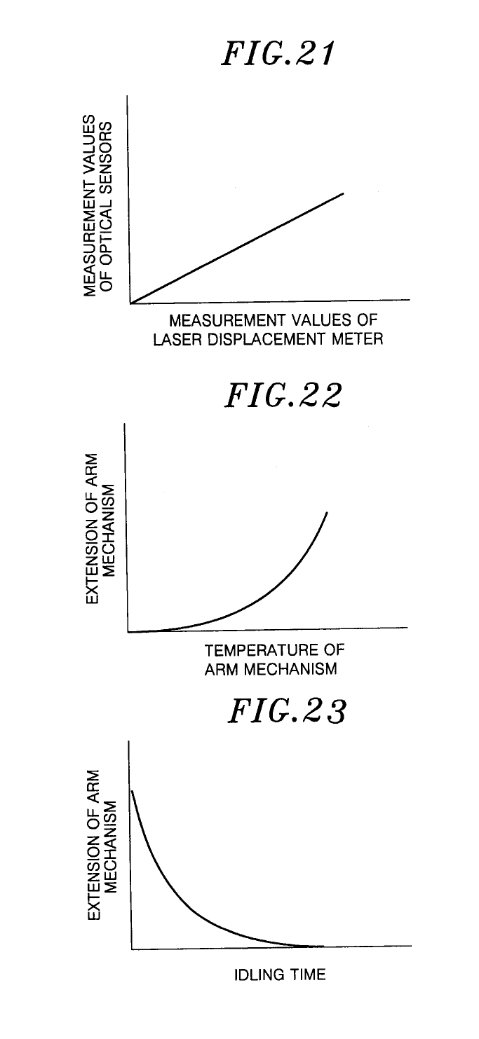

When the correction of extension of the arm mechanism is performed, the amount of extension of the arm mechanism is measured by a displacement meter such as a laser displacement meter, and as shown in FIG. 21, a correlation between the extension measured by the laser displacement meter and the measurement results of the position detection sensor unit 22 is obtained. Then, as shown in FIG. 22, a relationship between the extension of the arm mechanism and the temperature of the arm mechanism is obtained by using the laser displacement meter. Then, as shown in FIG. 23, a relationship between the idling time and the extension of the arm mechanism is obtained from the relationship between the idling time and the temperature of the arm mechanism. After idling, at the start of the transfer operation, the amount of extension of the arm mechanism is calculated on the basis of FIG. 23 from the idling time, and the operation of the arm mechanism is performed using the amount of extension as a correction value. Specifically, the wafer is placed on the pick immediately after becoming idle, and the amount of extension (correction value) of the arm mechanism when it resumes processing is determined based on the data of thermal expansion changes over time while idling, and the position correction is performed on the basis of the relationship shown in FIG. 21.

Accordingly, even after a long period of idling is performed, the amount of extension of the arm mechanism can be grasped, and when the wafer W is placed on the pick, it is possible to prevent the wafer W from being seated on the leading end side stopper pins 72 or the base end side stopper pins 73.

In addition, instead of obtaining in advance the correlation between the idling time and the measurement values of the laser displacement meter as described above, a displacement meter such a laser displacement meter may be provided in the substrate processing system 100, e.g., at an inlet portion of the load-lock chamber 6 (or 7) to directly measure the displacement of the arm mechanism.

(Other Applications)

In addition, the present invention can be variously modified without being limited to the embodiments described above. For example, in the embodiments described above, the multi-joint arm mechanism has been used as a substrate transfer mechanism, but other mechanisms such as a linear motion mechanism may be used without being limited thereto. Also, the optical sensor has been used as a sensor of the position detection sensor unit, but it is not limited thereto as long as it is to detect the position.

Further, two sensors have been used for one position detection sensor unit, but one sensor may be used. Further, although the position detection sensor unit has been provided in the vicinity of the loading/unloading port of the module (any one of the vacuum processing units and the load-lock chambers) to/from which the wafer is to be loaded/unloaded, it may be provided in a range in which the pick holding the wafer moves linearly for loading/unloading of the wafer. Further, in the above embodiments, the substrate processing system including four vacuum processing units and two load-lock chambers has been mentioned as an example, but they are not limited to these numbers. Furthermore, without being limited to a multi-chamber type vacuum processing apparatus having a plurality of vacuum processing units, the present invention is also applicable to a system having one vacuum processing unit. Moreover, as the substrate to be processed, other substrates such as a glass substrate for FPD may be used without being limited to the semiconductor wafer.

While the invention has been shown and described with respect to the embodiments, it will be understood by those skilled in the art that various changes and modification may be made without departing from the scope of the invention as defined in the following claims.

What is claimed is:

1. A substrate transfer device, which is provided in a transfer chamber to perform loading/unloading of a substrate to/from a vacuum processing unit in a substrate processing system including the vacuum processing unit in which a vacuum process accompanied by heat is performed and the transfer chamber connected to the vacuum processing unit and maintained in vacuum, the substrate transfer device comprising:
a pick which has one or more positioning pins to position the substrate and holds the positioned substrate;
a drive unit which drives the pick such that the substrate is loaded/unloaded to/from the vacuum processing unit by using the pick; and
a transfer control unit which controls a transfer operation of the substrate using the pick,
wherein the transfer control unit obtains in advance information on a reference position of the substrate at room temperature when the substrate is loaded into the vacuum processing unit, calculates a positional deviation from the reference position of the substrate when the substrate is loaded into the vacuum processing unit in actual processing, and controls the drive unit such that the substrate is loaded into the vacuum processing unit by correcting the positional deviation.

2. The substrate transfer device of claim 1, wherein the positioning pins are arranged on the pick such that the substrate is interposed between the positioning pins, and the substrate is positioned by pressing the substrate against the positioning pins by inertia when the pick is moved.

3. The substrate transfer device of claim 1, wherein the pick has a plurality of the positioning pins and the substrate transfer device further comprises a clamping mechanism to clamp the substrate on the pick by moving any one of the positioning pins.

4. The substrate transfer device of claim 3, further comprising a multi-joint arm mechanism including the pick and arms,
wherein the pick is rotatably provided with respect to an adjacent one of the arms,
wherein the clamping mechanism includes a cam which is displaced according to rotation of the pick, a moving member which moves the positioning pins back and forth by displacement of the cam to clamp or release the substrate, and an intermediate mechanism which transmits the displacement of the cam to the moving member, and
wherein a position of the cam is adjusted such that a back and forth movement of the positioning pins is determined in synchronization with a rotational position of the pick.

5. The substrate transfer device of claim 4, wherein the positioning pins include leading end side positioning pins provided on a leading end side of the pick and base end side positioning pins provided a base end side of the pick, and the clamping mechanism is configured to clamp or release the substrate by moving the base end side positioning pins back and forth, and
wherein the substrate is released in a range in which the pick has a negative acceleration when releasing the substrate on the pick to deliver the substrate by extending the multi-joint arm mechanism, and the substrate is clamped in a range in which the pick has a positive acceleration when clamping the substrate after receiving the substrate on the pick by retracting the multi-joint arm mechanism

6. The substrate transfer device of claim 1, wherein the reference position information is obtained based on detection information obtained by detecting the substrate at room temperature by a position detection sensor unit provided at a position where the substrate to be loaded/unloaded to/from the vacuum processing unit passes by.

7. The substrate transfer device of claim 6, wherein position information of the substrate when loading the substrate into the vacuum processing unit is obtained based on detection information obtained by detecting the substrate by the position detection sensor unit and a positional deviation is calculated from the position information of the substrate and the reference position information.

8. The substrate transfer device of claim 7, wherein detection of the positional deviation is performed when unloading the substrate from the vacuum processing unit or when loading the substrate into the vacuum processing unit, and correction of the positional deviation is performed when loading the substrate into the vacuum processing unit.

9. The substrate transfer device of claim 1, wherein the substrate processing system further includes a load-lock chamber which is connected to the transfer chamber and has a variable pressure between atmospheric ambience and vacuum to transfer the substrate to the transfer chamber in the vacuum state,
wherein the transfer control unit obtains in advance information on a reference position of the substrate at room temperature when the substrate is loaded into the load-lock chamber, calculates a positional deviation from the reference position of the substrate when the substrate is loaded into the load-lock chamber in actual processing, and controls the drive unit such that the substrate is loaded into the load-lock chamber by correcting the positional deviation.

10. The substrate transfer device of claim 1, wherein each of the positioning pins of the pick has a ring member rotatable about a vertical axis.

11. The substrate transfer device of claim 1, wherein the pick includes backside supporting pads swing to support a backside of the substrate and having rollers rotatable in a movement direction when positioning the substrate.

12. A substrate processing system comprising:
a vacuum processing unit in which a vacuum process accompanied by heat is performed;
a transfer chamber connected to the vacuum processing unit and maintained in vacuum; and
a substrate transfer device provided in the transfer chamber to perform loading/unloading of a substrate to/from the vacuum processing unit,
wherein the substrate transfer device includes:
a pick which has one or more positioning pins to position the substrate and holds the positioned substrate;
a drive unit which drives the pick such that the substrate is loaded/unloaded to/from the vacuum processing unit by using the pick; and
a transfer control unit which controls a transfer operation of the substrate using the pick,
wherein the transfer control unit obtains in advance information on a reference position of the substrate at room temperature when the substrate is loaded into the vacuum processing unit, calculates a positional deviation from the reference position of the substrate when the substrate is loaded into the vacuum processing unit in actual processing, and controls the drive unit such that the substrate is loaded into the vacuum processing unit by correcting the positional deviation.

13. The substrate processing system of claim 12, wherein the positioning pins are arranged on the pick such that the substrate is interposed between the positioning pins, and the substrate is positioned by pressing the substrate against the positioning pins by inertia when the pick is moved.

14. The substrate processing system of claim 12, the pick has a plurality of the positioning pins and the substrate transfer device further comprises a clamping mechanism to clamp the substrate on the pick by moving any one of the plurality of positioning pins.

15. The substrate processing system of claim 14, wherein the substrate transfer device comprises a multi-joint arm mechanism including the pick and arms,
wherein the pick is rotatably provided with respect to an adjacent one of the arms,
wherein the clamping mechanism includes a cam which is displaced according to rotation of the pick, a moving member which moves the positioning pins back and forth by displacement of the cam to clamp or release the substrate, and an intermediate mechanism which transmits the displacement of the cam to the moving member, and
wherein a position of the cam is adjusted such that a back and forth movement of the positioning pins is determined in synchronization with a rotational position of the pick.

16. The substrate processing system of claim 15, wherein the positioning pins include leading end side positioning pins provided on a leading end side of the pick and base end side positioning pins provided a base end side of the pick, and the clamping mechanism is configured to clamp or release the substrate by moving the base end side positioning pins back and forth, and
wherein the substrate is released in a range in which the pick has a negative acceleration when releasing the substrate on the pick to deliver the substrate by extending the multi-joint arm mechanism, and the substrate is clamped in a range in which the pick has a positive acceleration when clamping the substrate after receiving the substrate on the pick by retracting the multi-joint arm mechanism.

17. The substrate processing system of claim 12, wherein the reference position information is obtained based on detection information obtained by detecting the substrate at room temperature by a position detection sensor unit provided at a position where the substrate to be loaded/unloaded to/from the vacuum processing unit passes by.

18. The substrate processing system of claim 17, wherein position information of the substrate when loading the substrate into the vacuum processing unit is obtained based on detection information obtained by detecting the substrate by the position detection sensor unit and a positional deviation is calculated from the position information of the substrate and the reference position information.

19. The substrate processing system of claim 18, wherein detection of the positional deviation is performed when unloading the substrate from the vacuum processing unit or when loading the substrate into the vacuum processing unit, and correction of the positional deviation is performed when loading the substrate into the vacuum processing unit.

20. The substrate processing system of claim 12, further comprising a load-lock chamber which is connected to the transfer chamber and has a variable pressure between atmospheric ambience and vacuum to transfer the substrate to the transfer chamber in the vacuum state,
wherein the transfer control unit obtains in advance information on a reference position of the substrate at room temperature when the substrate is loaded into the load-lock chamber, calculates a positional deviation from the reference position of the substrate when the substrate is loaded into the load-lock chamber in actual processing, and controls the drive unit such that the substrate is loaded into the load-lock chamber by correcting the positional deviation.
